(19) United States
(12) Patent Application Publication
(10) Pub. No.: US 2026/0211196 A1
(43) Pub. Date: Jul. 23, 2026

(54) OPTICAL FIBER ARRAY CAPABLE OF ALIGNMENT AND ALIGNMENT METHOD THEREOF

(71) Applicant: HERMES TESTING SOLUTIONS INC., Hsinchu City (TW)

(72) Inventor: Wen-Yuan Hsu, Hsinchu City (TW)

(73) Assignee: HERMES TESTING SOLUTIONS INC., Hsinchu City (TW)

(21) Appl. No.: 19/181,336

(22) Filed: Apr. 17, 2025

Related U.S. Application Data
(60) Provisional application No. 63/747,347, filed on Jan. 21, 2025.

(30) Foreign Application Priority Data
Apr. 2, 2025 (TW) 114112699

(51) Int. Cl. G02B 6/42

(52) U.S. Cl. CPC G02B 6/4221; G02B 6/4227

(57) ABSTRACT

Provided is an optical fiber array capable of alignment for a silicon photonics wafer testing system including a base, a lid, a plurality of fiber optics, and a plurality of marks. The base has a first endface and a plurality of grooves, and one lateral opening of each groove is located on the first endface. The lid has a second endface and is stacked onto the base to cover the grooves and portions of the fiber optics in the grooves and expose the lateral openings. The first endface, light emitting/receiving surfaces of the fiber optics, and the second endface are located on a same plane. The marks are respectively disposed on the first endface and the second endface and outside a range where the fiber optics are located. An alignment method of an optical fiber array is also provided.

### CROSS-REFERENCE TO RELATED APPLICATION

This application claims the priority benefits of U.S. provisional application serial no. 63/747,347, filed on January 21, 2025, and Taiwan application serial no. 114112699, filed on April 2, 2025. The entirety of each of the above-mentioned patent applications is hereby incorporated by reference herein and made a part of this specification.

### BACKGROUND

### Technical Field

The disclosure relates to an optical fiber array capable of alignment and an alignment method thereof.

### Related Art

In the existing silicon photonics wafer testing, two separate steps are needed to position (align) the optical fiber array and coupler. Step one is to manually move the fiber optic or optical fiber array (FA) to an approximate position above the grating coupler (GC) or edge coupler (EC). Afterward, Step two uses a downward-facing camera or side-view camera plus a 45-degree prism optical lens to find the side image line of the fiber optic or optical fiber array as a reference. Then, the coordinate position of the reference is used as the starting point for optical coupling.

However, the errors generated by the above Steps one and two are large, requiring a large search range to find the initial light and coupling peak, which consumes a significant amount of time. In Step one, the manual movement plus visual manual alignment error is approximately +/-500um, while in Step two, the total error caused by structural chipping or cracking in the body structure of the fiber optic or optical fiber array due to manufacturing or caused by visual focusing is approximately +/-105um.

In particular, existing optical fiber arrays are made by mounting multiple fiber optics between a base and a lid, bonding then bonded together using adhesive curing, and then processed through a polishing process to polish the endface of one side to the required angle, ensuring to align with the necessary angle for light propagation to the chip coupler. Therefore, in the above process of manual movement plus visual manual alignment, errors generated during the glass base manufacturing process and polishing process affect the accuracy of subsequent alignment and optical coupling and the search time consumed.

### SUMMARY

The disclosure provides an optical fiber array capable of alignment and an alignment method thereof, which adjusts the optical fiber array to the correct position through active alignment, thereby reducing positioning time and benefiting subsequent optical coupling and testing operations.

The optical fiber array capable of alignment of the disclosure is adapted for a silicon photonics wafer testing system. The silicon photonics wafer testing system includes a wafer prober and an optical coupling actuator, with the optical fiber array loaded on the optical coupling actuator, the optical coupling actuator disposed on the wafer prober, and the silicon photonics wafer loaded on the wafer prober. The wafer prober aligns the optical fiber array to achieve a state where the aligned optical fiber array can optically couple with the coupler of the silicon photonics wafer. The optical fiber array includes multiple fiber optics, a base, a lid, and multiple marks. The base has a first endface and multiple grooves parallel to each other, the fiber optics are disposed in the grooves, and one lateral opening of each groove is located on the first endface. The lid is stacked on the base, covering the grooves and portions of the fiber optics in the grooves and exposing the lateral openings. The lid has a second endface, and the first endface of the base, the light emitting/receiving surface of the fiber optics, and the second endface of the lid are located on a same plane. The marks are respectively disposed on the first endface and the second endface. In the plane, the marks are located outside a range where the fiber optics are located.

The alignment method of the optical fiber array of the disclosure is for aligning the optical fiber array in the silicon photonics wafer testing system as described above. The alignment method of the optical fiber array includes the following. An upward-facing camera of the wafer prober is driven to detect the optical fiber array. Spatial coordinates of a light emitting/receiving surface of each fiber optic in the wafer prober and spatial coordinates of marks in the wafer prober are obtained. Relative position difference and relative angle difference of the optical fiber array with respect to the silicon photonics wafer are calculated.

Based on the above, the optical fiber array, through the marks disposed on the endface thereof for optical alignment, may be detected and aligned by the upward-facing camera of the wafer prober, thereby obtaining the spatial coordinates of the fiber optics and marks of the optical fiber array in the wafer prober, and accordingly calculating the relative position difference and relative angle difference of the optical fiber array with respect to the silicon photonics wafer, which is equivalent to obtaining the relative positional relationship between the optical fiber array and the silicon photonics wafer (including the coupler and bonding pad thereof), so that the correction amount needed to drive the optical fiber array to the correct optical coupling position can be obtained through calculation, achieving the benefit of rapid subsequent optical coupling.

In the silicon photonics wafer testing system, compared to the poor optical coupling efficiency of existing optical fiber arrays due to errors caused by clamping mechanisms or polishing processes, this disclosure, through the rapid alignment actively provided to the optical fiber array as described above, can effectively reduce the time and complexity required for optical coupling alignment and subsequent optical testing and opto-electronic testing, thereby improving the efficiency of optical coupling and testing.

### BRIEF DESCRIPTION OF THE DRAWINGS

FIG. 1A is a schematic view of a silicon photonics wafer testing system according to an embodiment of the disclosure.

FIG. 1B is a schematic view of the silicon photonics wafer testing system performing opto-electronic testing.

FIG. 2 is a schematic view of an optical fiber array.

FIG. 3 is a side view of the optical fiber array in FIG. 2.

FIG. 4A to FIG. 4D illustrate schematic views of a corresponding relationship between the optical fiber array and the silicon photonics wafer.

FIG. 5A to FIG. 5H illustrate side views of the optical fiber array according to different embodiments.

### DESCRIPTION OF THE EMBODIMENTS

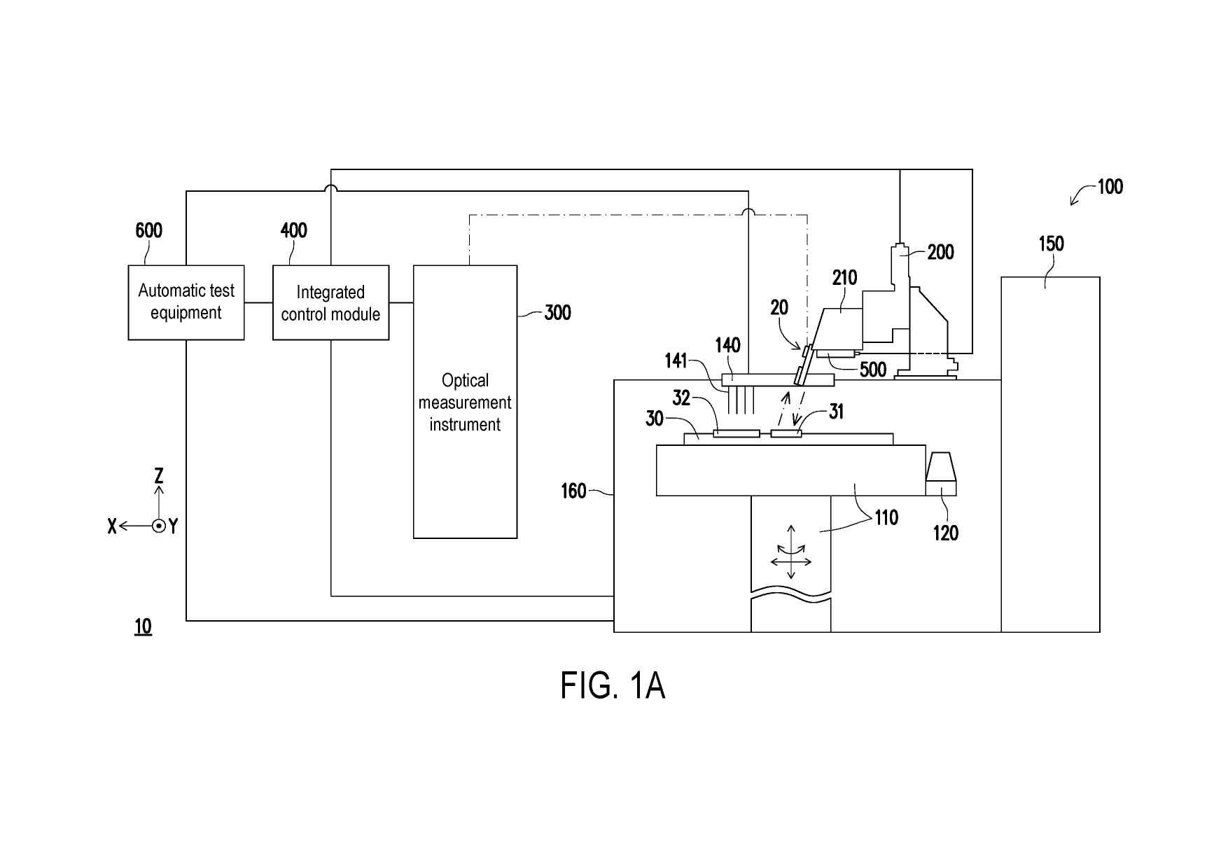

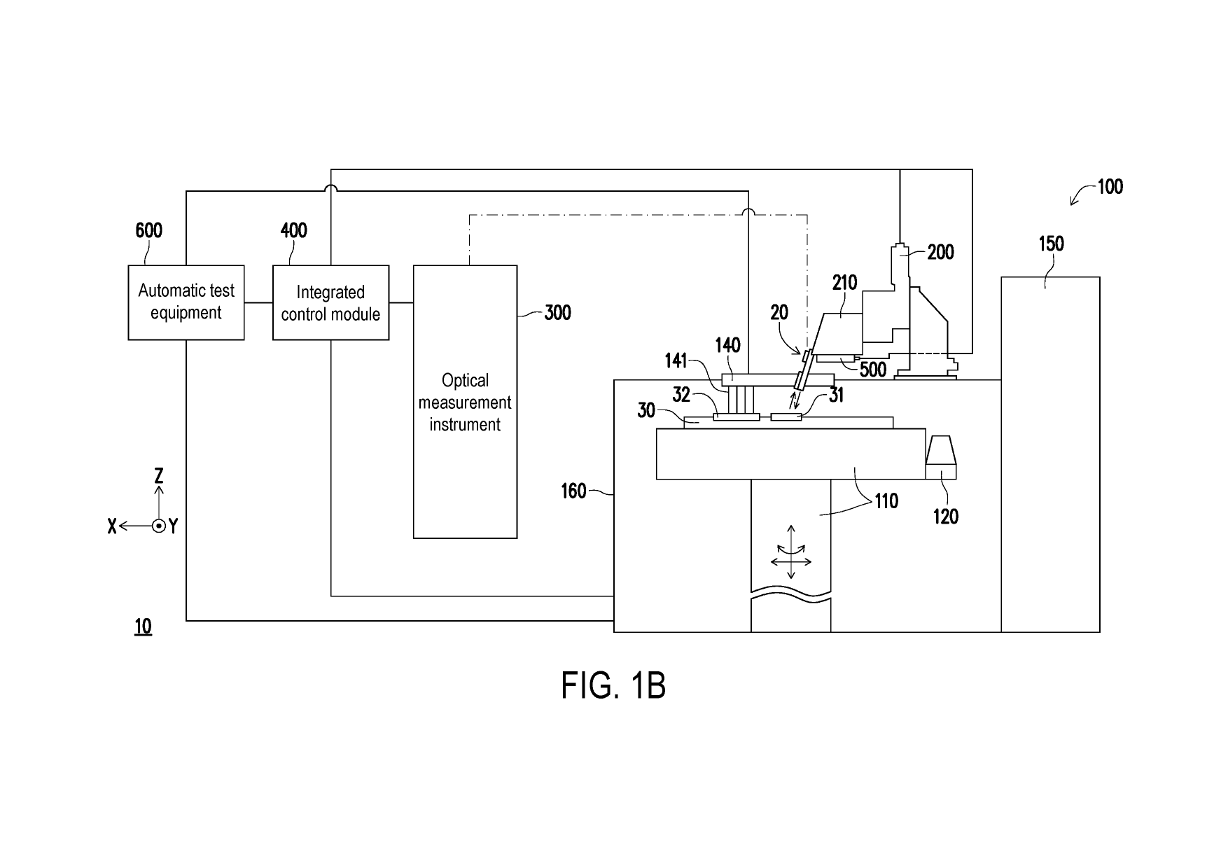

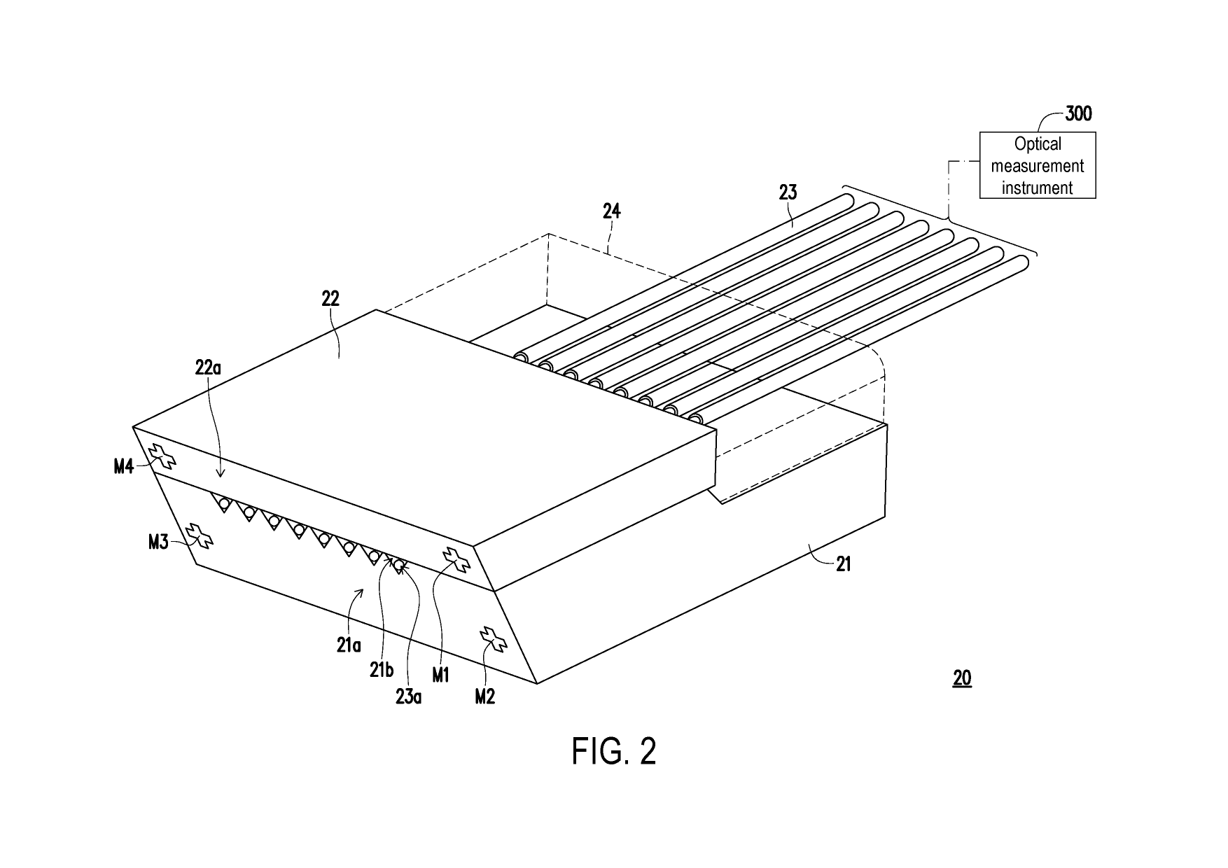

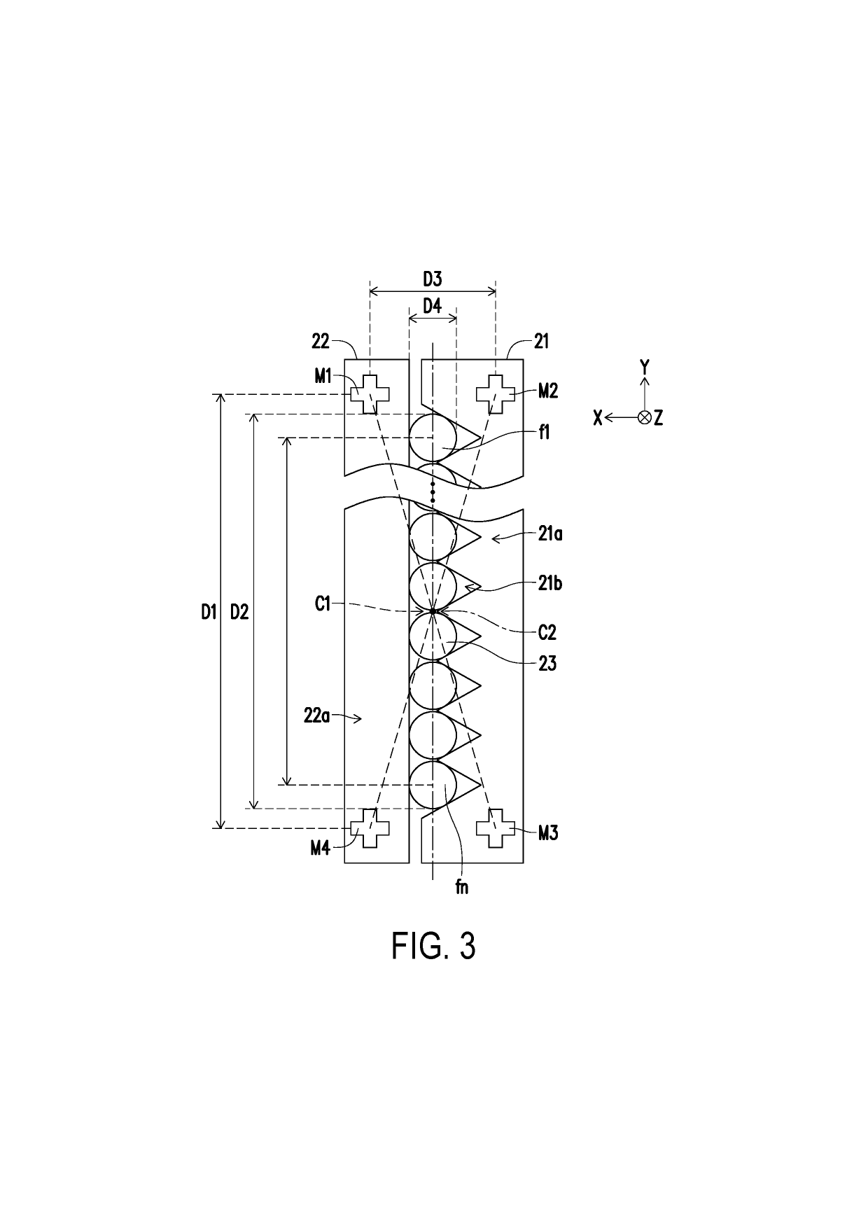

FIG. 1A is a schematic view of a silicon photonics wafer testing system according to an embodiment of the disclosure. FIG. 2 is a schematic view of an optical fiber array. FIG. 3 is a side view of the optical fiber array in FIG. 2. Referring to FIG. 1A to FIG. 3 simultaneously, in this embodiment, an optical fiber array 20 capable of alignment (hereinafter referred to as the optical fiber array 20) is adapted for a silicon photonics wafer testing system 10, so as to complete alignment and optical coupling operations through the silicon photonics wafer testing system 10. The silicon photonics wafer testing system 10 includes a wafer prober 100 and an optical coupling actuator 200, the optical fiber array 20 is loaded on the optical coupling actuator 200, the optical coupling actuator 200 is disposed on the wafer prober 100, the silicon photonics wafer 30 is loaded on the wafer prober 100, and after aligning the optical fiber array 20 through the wafer prober 100, the optical fiber array 20 reaches a state of being able to optically couple with a coupler 31 of the silicon photonics wafer 30, which is beneficial for subsequently completing opto-electronic testing operations with the silicon photonics wafer testing system 10.

In this embodiment, the wafer prober 100 includes a stage 110, a probe card 140, a probe testing platform 160, an upward-facing camera 120, and a wafer transporter 150. The stage 110, for example, is a movable stage, which may be drivably disposed in the probe testing platform 160. The optical coupling actuator 200 is disposed on the probe testing platform 160, the wafer transporter 150 is disposed beside the probe testing platform 160, to transport and load the silicon photonics wafer 30 onto the stage 110, or to remove it from the stage 110. The probe card 140 is disposed on the probe testing platform 160, the probe card 140 has an opening to allow the optical coupling actuator 200 to drive the optical fiber array 20 to pass through, and extend into the probe testing platform 160, to perform optical coupling with the coupler 31 (for example, a grating coupler or edge coupler) of the silicon photonics wafer 30 and related optical testing or opto-electronic testing.

Moreover, the silicon photonics wafer testing system 10 further includes an optical measurement instrument 300, an integrated control module 400, a distance sensor 500, and an automatic test equipment (ATE) 600, in which the optical measurement instrument 300, in addition to including a light source and related optical components that can provide light to the optical fiber array 20, also includes optical components and receivers that can receive light returned from the optical fiber array 20, and thereby evaluate the effect on the light during the optical coupling process between the optical fiber array 20 and the coupler 31. The distance sensor 500 and the optical fiber array 20 are respectively disposed (or clamped) on the fiber holder 210 of the optical coupling actuator 200 to move with the fiber holder 210, in which the distance sensor 500 is used to correspond to the coupler 31 of the silicon photonics wafer 30, to obtain the relative position difference (for example, height difference) between the optical fiber array 20 and the coupler 31, and thereby serve as verification when the upward-facing camera 120 aligns the optical fiber array 20. The automatic test equipment 600 is integrated into the wafer prober 100 and electrically connected to the integrated control module 400 and electrically connected to the probe card 140, so as to allow the integrated control module 400 to drive the automatic test equipment 600 to detect the electrical characteristics or opto-electronic characteristics of the silicon photonics wafer 30. The integrated control module 400 is electrically connected to the wafer prober 100, the optical coupling actuator 200, the optical measurement instrument 300, the distance sensor 500, and the automatic test equipment 600, to integrate the above into the silicon photonics wafer testing system 10, and to smoothly execute the alignment of the optical fiber array 20, the alignment of the silicon photonics wafer 30, the optical coupling between the optical fiber array 20 and the silicon photonics wafer 30, and the subsequent optic-to-optic testing.

In addition, the upward-facing camera 120 of this embodiment is disposed on the side of the stage 110, to move with the stage 110 in the probe testing platform 160, thereby performing related alignment or detection actions for the probe card 140 and the optical fiber array 20.

FIG. 1B is a schematic view of the silicon photonics wafer testing system performing opto-electronic testing. Referring to FIG. 1B and in comparison with FIG. 1A, FIG. 1B similarly shows the opto-electronic (optic-to-electric) testing performed after completing the alignment of the optical fiber array 20, the alignment of the silicon photonics wafer 30, and the optical coupling between the optical fiber array 20 and the silicon photonics wafer 30, that is, allowing the probe 141 of the probe card 140 to contact a bonding pad 32 and electrify, to obtain the opto-electronic characteristic relationship between the optical fiber array 20 and the silicon photonics wafer 30. In this embodiment, rectangular coordinates X-Y-Z are provided based on the wafer prober 100 to facilitate the subsequent component description.

As shown in FIG. 2 and FIG. 3, the optical fiber array 20 of this embodiment includes multiple fiber optics 23, a base 21, a lid 22, and multiple marks (a mark one M1, a mark two M2, a mark three M3, and a mark four M4). The base 21 has a first endface 21a and multiple (V-shaped) grooves 21b parallel to each other, in which the base 21 viewed from the right side appears as a stepped structure, and the grooves 21b are located at the higher step of the stepped structure. The fiber optics 23 are disposed in the grooves 21b respectively, and one lateral opening of each groove 21b (that is, the opening shown in FIG. 2) is located on the first endface 21a. In FIG. 2, another lateral opening of each groove 21b is located on another side (that is, the opposite side of the first endface 21a) of the stepped structure of the base 21 and is not shown. The lid 22 is stacked on the base 21, covering the grooves 21b and portions of the fiber optics 23 in the grooves 21b and exposing the lateral openings of the grooves 21b, and the three are combined and fixed through a bonding member 24. The lid 22 has a second endface 22a, in which the first endface 21a of the base 21, the light emitting/receiving surface 23a of the fiber optics 23, and the second endface 22a of the lid 22 are located on a same plane (located in the same first plane P1, and the first plane P1 of this embodiment is substantially the X-Y plane or parallel to the X-Y plane).

In addition, the multiple marks (the mark one M1, the mark two M2, the mark three M3, and the mark four M4) of this embodiment are respectively disposed on the first endface 21a and the second endface 22a, and as shown in FIG. 3, on the first plane P1, the marks (the mark one M1, the mark two M2, the mark three M3, and the mark four M4) are located outside a range where the fiber optics 23 are located. Furthermore, the fiber optics 23 are arranged along the Y-axis, and the base 21, the fiber optics 23, and the lid 22 are stacked along the X-axis. Here, a first relative distance D1 along the Y-axis between two marks (for example, the mark one M1 and the mark four M4, or the mark two M2 and the mark three M3) is greater than an array length D2 of the fiber optics 23 along the Y-axis, and a second relative distance D3 along the X-axis between two marks (for example, the mark one M1 and the mark two M2, or the mark three M3 and the mark four M4) is greater than an array length D4 of the fiber optics 23 along the X-axis.

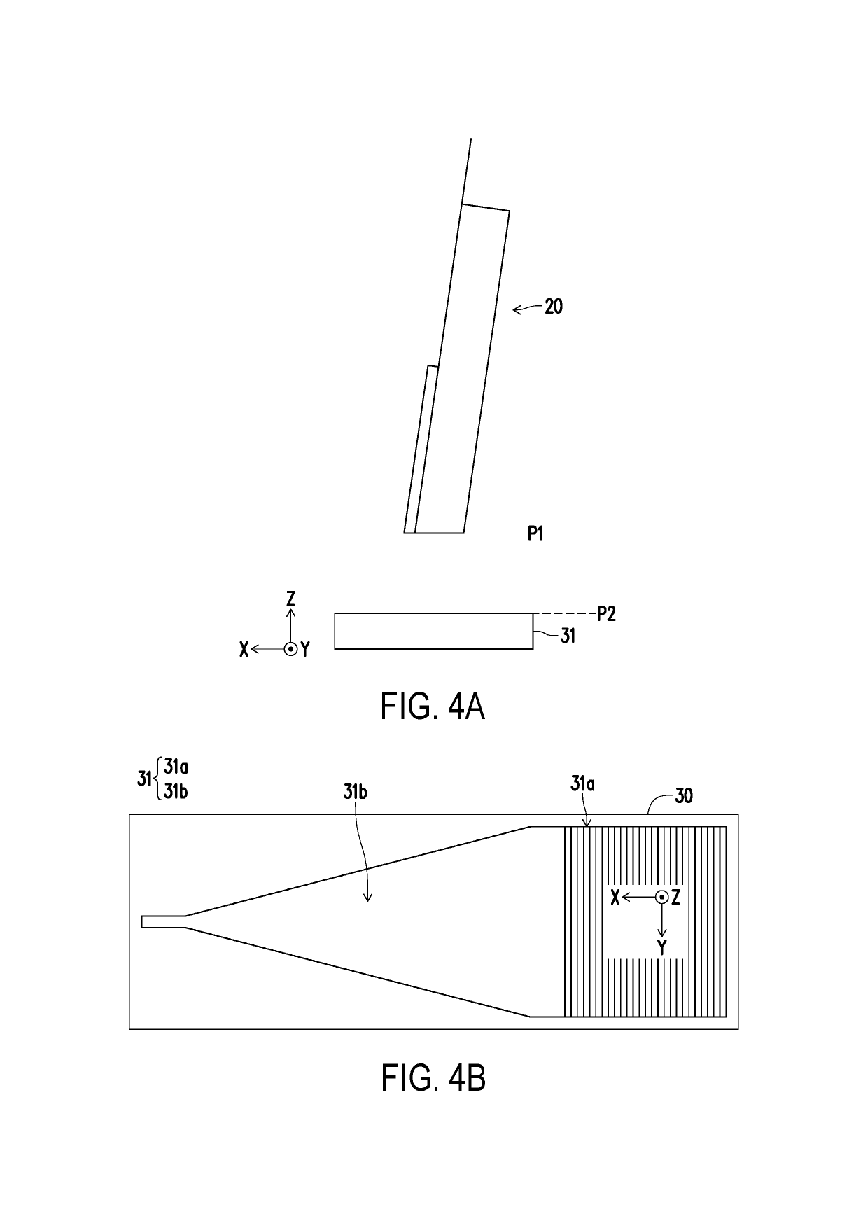

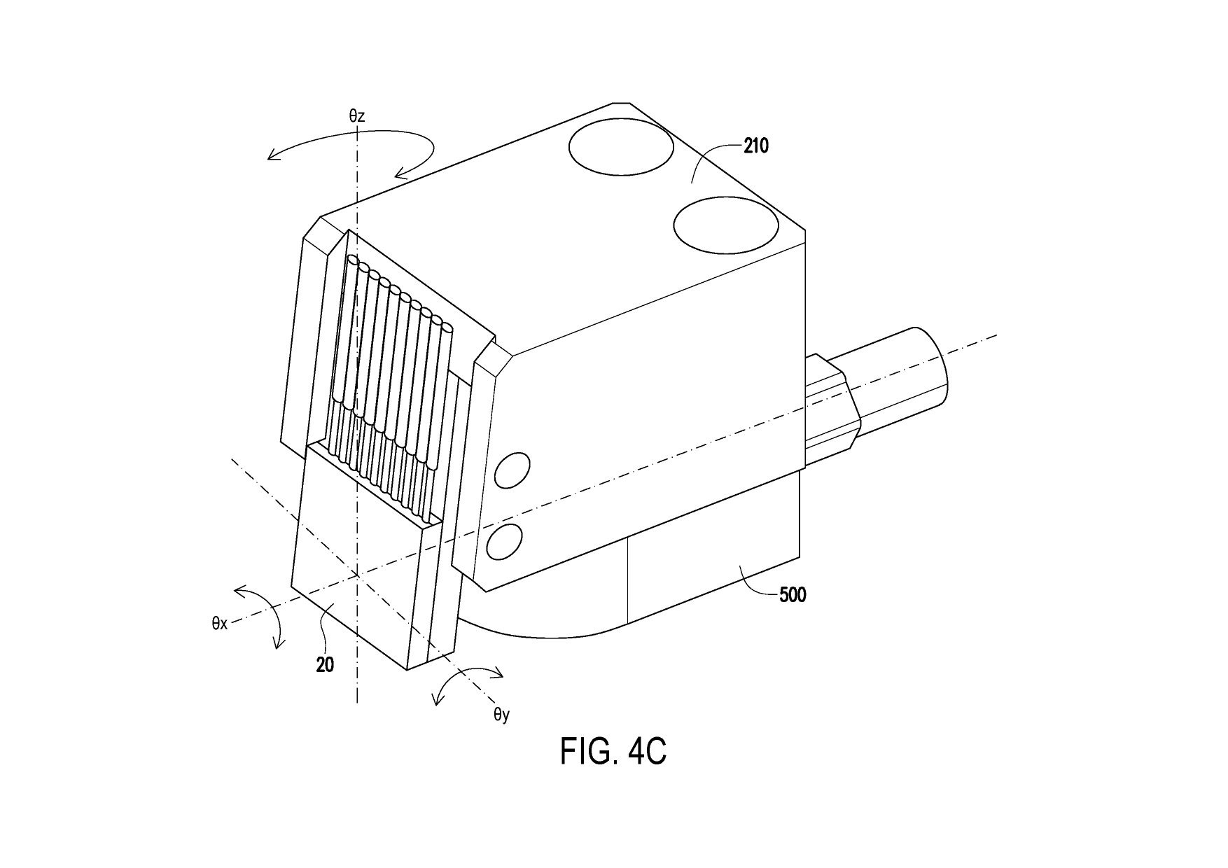

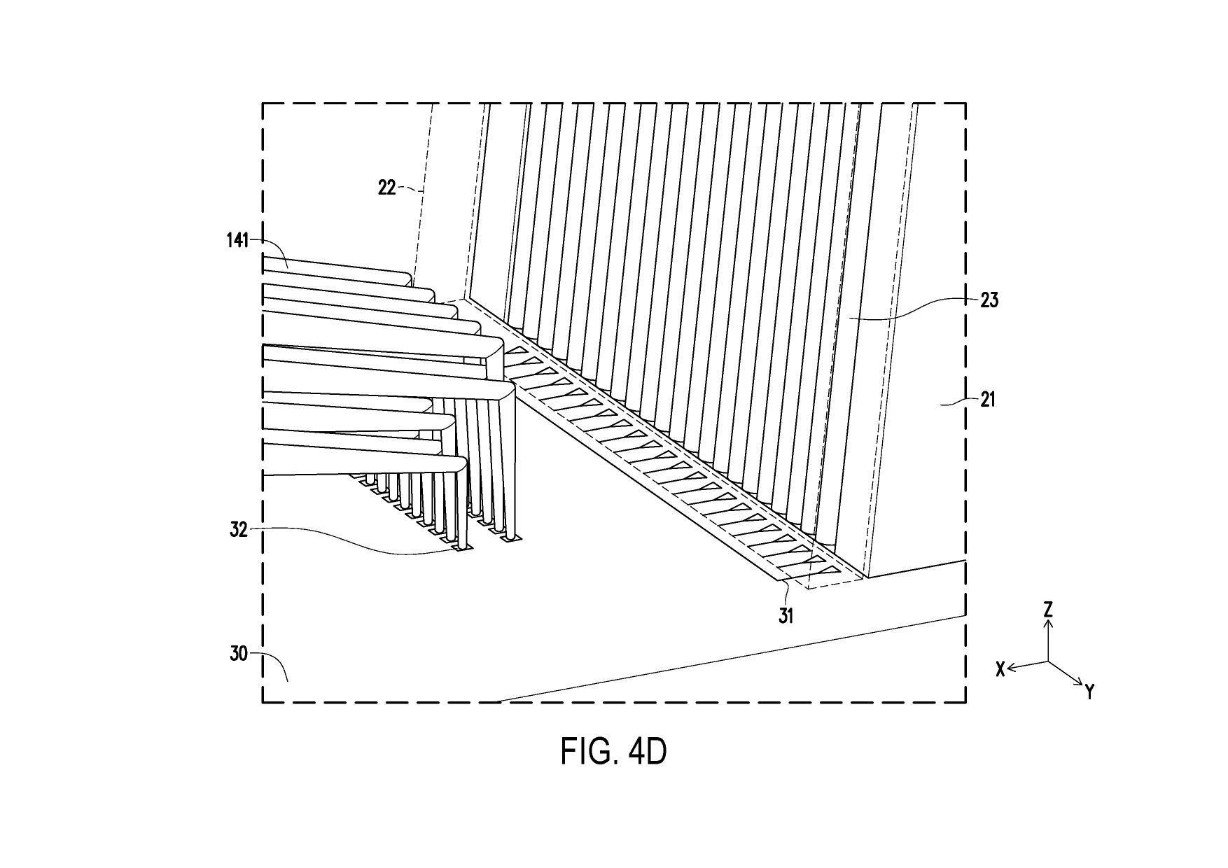

FIG. 4A to FIG. 4D illustrate schematic views of a corresponding relationship between the optical fiber array and the silicon photonics wafer, which serve as a reference for the subsequent description of the alignment method steps. As mentioned earlier, the wafer prober 100 of this embodiment may provide alignment functionality for the optical fiber array 20, to facilitate the optical fiber array 20 being driven to the correct position in advance, which is beneficial for subsequent optical coupling and testing. In this case, the optical fiber array 20 uses the mark one M1, the mark two M2, the mark three M3, and the mark four M4 as shown in FIG. 3 as examples. Taking the range where the fiber optics 23 are disposed as a square range on the first plane P1 as an example, the mark one M1, the mark two M2, the mark three M3, and the mark four M4 are equivalent to being located outside the square range to form another square range, and the mark one M1, the mark two M2, the mark three M3, and the mark four M4 are respectively located at four different corners of the another square range, in which the mark two M2 and the mark three M3 are located on the first endface 21a, and the mark one M1 and the mark four M4 are located on the second endface 22a. The mark one M1 and the mark three M3 are diagonally disposed, while the mark two M2 and the mark four M4 are diagonally disposed.

Based on the above mark configuration, the alignment method of the optical fiber array 20 in the disclosure includes the following. Through the integrated control module 400, the upward-facing camera 120 of the wafer prober 100 is driven to detect and align the optical fiber array 20. Coordinates of the center of the light emitting/receiving surface 23a of each fiber optic 23 and center coordinates of the marks (the mark one M1, the mark two M2, the mark three M3, and the mark four M4) are obtained, and then using the coupler 31 on a second plane P2 (the plane P2 is substantially the X-Y plane or parallel to the X-Y plane) as a reference, so as to calculate the relative position difference and the relative angle difference of the fiber optics 23 and the marks (the mark one M1, the mark two M2, the mark three M3, and the mark four M4) with respect to the coupler 31, in order to understand the relative positional relationship between the optical fiber array 20 and the coupler 31 within the wafer prober 100. Here, the coupler 31 includes, for example, the grating 31a and the waveguide 31b shown in FIG. 4B and FIG. 4D. After being emitted from the first plane P1 of the optical fiber array 20, light is directed toward the grating 31a of the coupler 31, and then transmitted through the waveguide 31b. The corresponding relationship of the relevant components may be understood from the rectangular coordinates X-Y-Z shown in FIG. 4A and FIG. 4B. The rectangular coordinates X-Y-Z may be viewed as the coordinate system of the operating space of the wafer prober 100.

In this embodiment, the relative angle difference includes a rotational angle difference (θₓ) relative to the X-axis, a rotational angle difference (θ_{y}) relative to the Y-axis, and a rotational angle difference (θ_{z}) relative to the Z-axis, in which the upward-facing camera 120 is used for alignment and the spatial coordinates (rectangular coordinates X-Y-Z) of the mark one M1, the mark two M2, the mark three M3, and the mark four M4 are obtained, to calculate and obtain the rotational angle difference (θₓ) and the rotational angle difference (θ_{y}). Furthermore, through the upward-facing camera 120 for alignment, the spatial coordinates (rectangular coordinates X-Y-Z) of a first fiber f1 and the spatial coordinates (rectangular coordinates X-Y-Z) of a last fiber fn are obtained, to calculate and obtain the rotational angle difference (θ_{z}) and subsequently establish a preset distance for use when coupling with the grating 31a.

In addition, due to the coupling angle requirements of the fiber optic 23, the relative position difference includes a height difference along the Z-axis. As shown in FIG. 4A, the height difference is obtained by calculating the coordinate differences along the Z-axis of the mark one M1, the mark two M2, the mark three M3, and the mark four M4 to obtain the Z-axis coordinate of the center (the center coordinate C2) of the optical fiber array 20.

In another embodiment, the rotational angle difference (θ_{z}) may also be calculated through the rectangular coordinates X-Y-Z differences of each mark (the mark one M1, the mark two M2, the mark three M3, and the mark four M4) relative to the first fiber f1 of the fiber optics 23, and through the rectangular coordinates X-Y-Z differences of each mark (the mark one M1, the mark two M2, the mark three M3, and the mark four M4) relative to the last fiber fn of the fiber optics 23. This operation provides an additional method for obtaining the rotational angle difference (θ_{z}), in order to accommodate various usage requirements.

At this point, after the silicon photonics wafer 30 is loaded onto the stage 110, the corresponding position of the coupler 31 thereof in the operating space of the wafer prober 100 becomes known (as mentioned above, based on rectangular coordinates X-Y-Z), thus enabling the driving of the upward-facing camera 120 to detect and align the optical fiber array 20 in the first plane P1, to calculate the difference amount of the relative position parameters (X,Y,Z,θₓ,θ_{y},θ_{z}) of the fiber optic 23 and the multiple marks (the mark one M1, the mark two M2, the mark three M3, and the mark four M4) relative to the second plane P2, thereby providing the optical coupling actuator 200 with the difference amount for position correction through the fiber holder 210 thereof, which enables the optical coupling actuator 200 to smoothly drive the optical fiber array 20 to a position where it can complete coupling with the coupler 31. Thus, the optical fiber array 20 and the silicon photonics wafer 30 that have completed coupling may subsequently undergo optical testing with the silicon photonics wafer testing system 10, or additionally have the probes 141 of the probe card 140 press against the bonding pads 32 of the silicon photonics wafer 30 (as shown in FIG. 4D), and based on this, the relative positional relationship between the two may be known, allowing for subsequent opto-electrical testing with the silicon photonics wafer testing system 10.

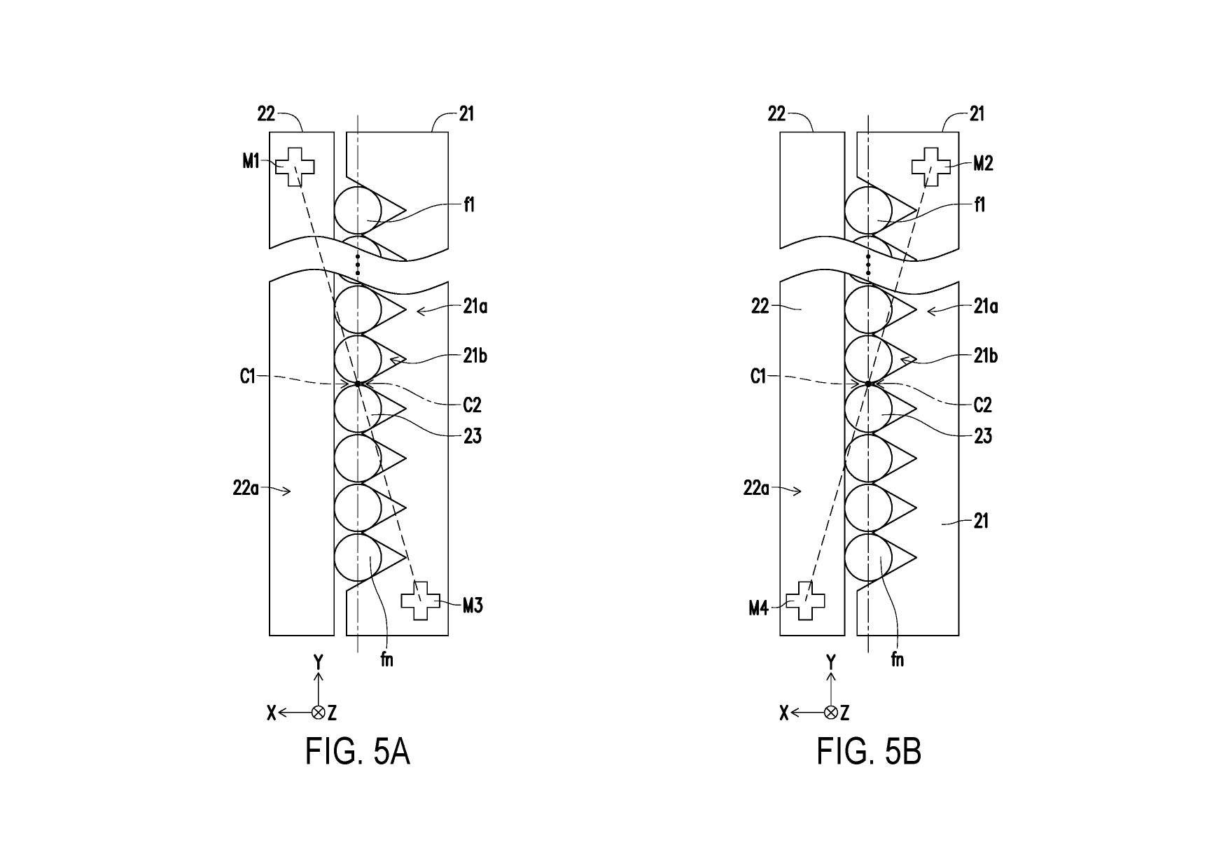

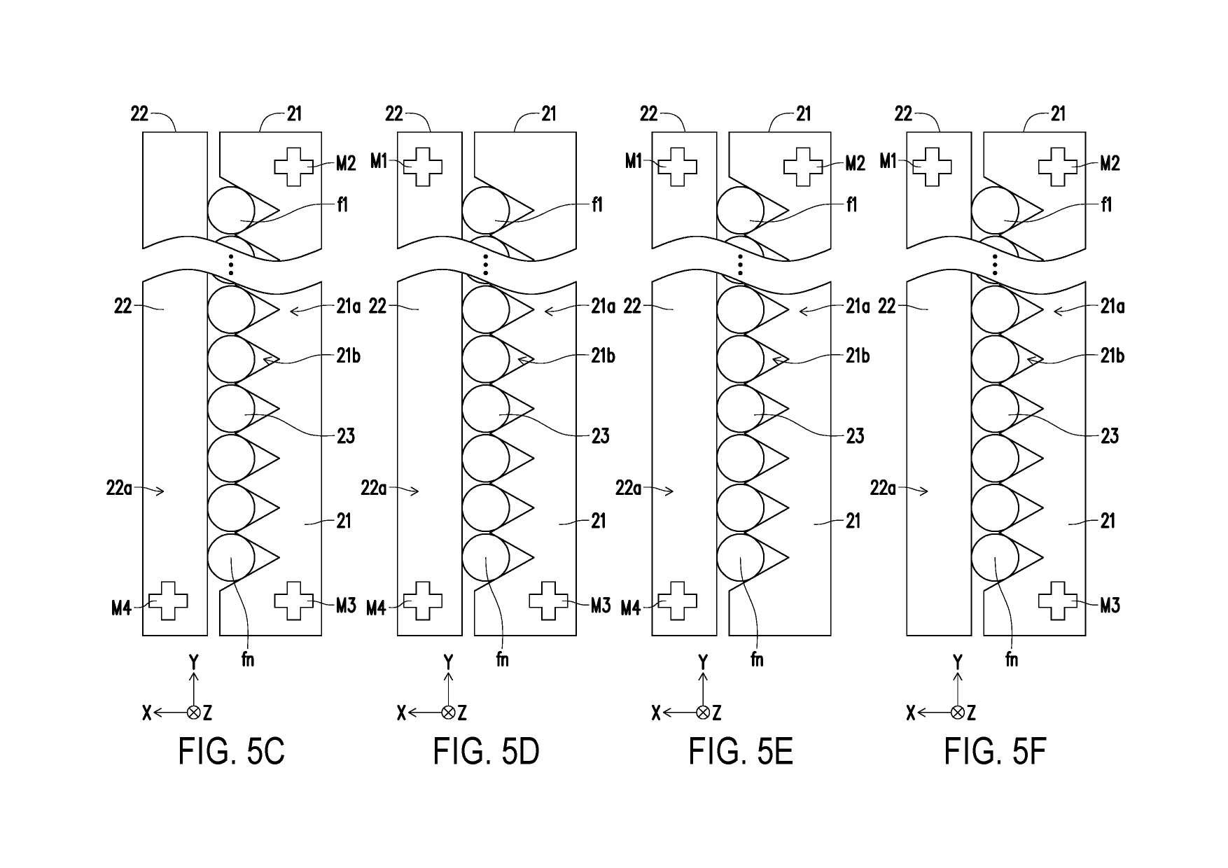

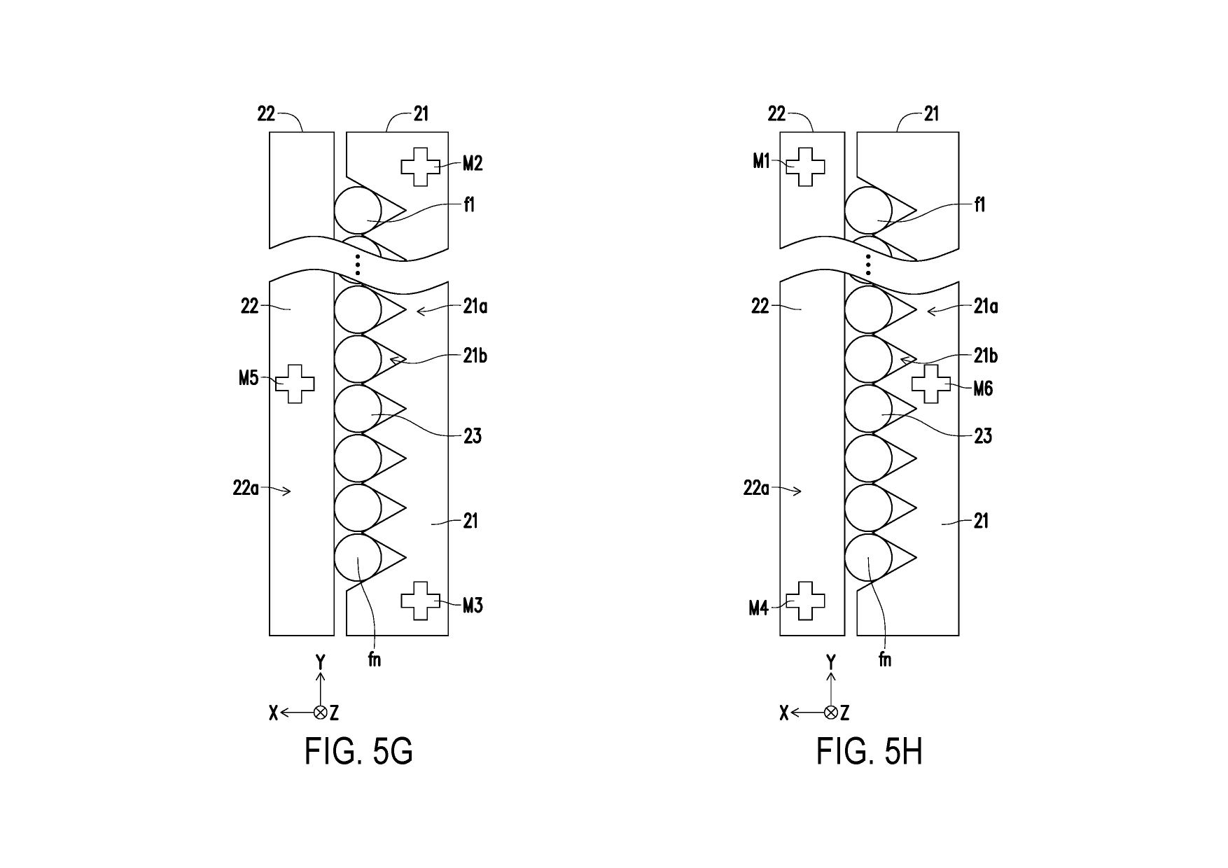

FIG. 5A to FIG. 5H illustrate side views of the optical fiber array according to different embodiments. Referring to FIG. 5A to FIG. 5H respectively, unlike the previously described embodiment of the optical fiber array 20 with the four marks (the mark one M1, the mark two M2, the mark three M3, and the mark four M4), different embodiments shown in the disclosure may also respectively achieve the requirement of obtaining the relative position parameters (X,Y,Z,θₓ,θ_{y},θ_{z}) of the optical fiber array 20 relative to the coupler 31.

First, as shown in FIG. 5A, two marks (the mark one M1, the mark three M3) are diagonally disposed relative to the fiber optic 23, thus after detecting the mark one M1, the mark three M3, and each light emitting/receiving surface 23a of the fiber optic 23 with the upward-facing camera 120 to obtain the respective spatial coordinates thereof, center coordinates C1 and center coordinates C2 may be further calculated. Then, through the planar distance difference along the X-axis and the height coordinate difference along the Z-axis between the mark one M1 and the mark three M3, the rotational angle difference (θ_{y}) may be calculated; through the planar distance difference along the Y-axis and the height coordinate difference along the Z-axis between the mark one M1 and the mark three M3, the rotational angle difference (θₓ) may be calculated; through the spatial coordinates of the center of the first fiber f1 and the center of the last fiber fn of the fiber optics 23, the rotational angle difference (θ_{z}) may be obtained. In addition, as provided in another method mentioned above, the rotational angle difference (θ_{z}) may also be calculated here through the difference between the center coordinate C1 obtained from the mark one M1 and the mark three M3 and the center coordinates C2 of the fiber optic 23.

Please refer to FIG. 5B, which is consistent with the alignment method shown in FIG. 5A, except that the mark objects are changed to the mark two M2 and the mark four M4. Accordingly, after detecting the mark two M2, the mark four M4, and each light emitting/receiving surface 23a of the fiber optic 23 with the upward-facing camera 120 to obtain the respective spatial coordinates thereof, the center coordinates C1 and the center coordinates C2 may be further calculated. Then, through the planar distance difference along the X-axis and the height coordinate difference along the Z-axis between the mark two M2 and the mark four M4, the rotational angle difference (θ_{y}) may be calculated; through the planar distance difference along the Y-axis and the height coordinate difference along the Z-axis between the mark two M2 and the mark four M4, the rotational angle difference (θₓ) may be calculated; through the spatial coordinates of the center of the first fiber f1 and the center of the last fiber fn of the fiber optics 23, the rotational angle difference (θ_{z}) may be obtained. Similar to the above, the rotational angle difference (θ_{z}) may also be calculated through the difference between the center coordinates C1 obtained from the mark two M2 and the mark four M4 and the center coordinates C2 of the fiber optic 23.

Referring to FIG. 5C, the drawing contains the mark two M2, the mark three M3, and the mark four M4. Therefore, after detecting the mark two M2, the mark three M3, and the mark four M4, and each light emitting/receiving surface 23a of the fiber optic 23 with the upward-facing camera 120 to obtain the respective spatial coordinates thereof, the center coordinates C1, C2 may be further obtained. Subsequently, through the planar distance difference along the X-axis and the height coordinate difference along the Z-axis between the mark two M2 and the mark four M4, and through the planar distance difference along the X-axis and the height coordinate difference along the Z-axis between the mark three M3 and the mark four M4, the rotational angle difference (θ_{y}) may be calculated; through the planar distance difference along the Y-axis and the height coordinate difference along the Z-axis between the mark two M2 and the mark three M3, as well as the height coordinate difference along the Y-axis and Z-axis between the mark two M2 and the mark four M4, the rotational angle difference (θₓ) may be calculated; through the spatial coordinates of the center of the first fiber f1 and the center of the last fiber fn of the fiber optics 23, the rotational angle difference (θ_{z}) may be obtained. Alternatively, through the difference between the center coordinates C1 obtained from the mark two M2, the mark three M3, and the mark four M4 and the center coordinates C2 of the fiber optic 23, the rotational angle difference (θ_{z}) may be calculated.

Please refer to FIG. 5D, which is similar to FIG. 5C, and the drawing contains the mark one M1, the mark three M3, and the mark four M4. Therefore, after detecting the mark one M1, the mark three M3, and the mark four M4, and each light emitting/receiving surface 23a of the fiber optic 23 with the upward-facing camera 120 to obtain the respective spatial coordinates thereof, the center coordinates C1 (obtained from the mark one M1, the mark three M3, and the mark four M4) and the center coordinates C2 (obtained from the light emitting/receiving surface 23a of the fiber optic 23) may be further obtained. Subsequently, through the planar distance difference along the X-axis and the height coordinate difference along the Z-axis between the mark one M1 and the mark three M3, and through the planar distance difference along the X-axis and the height coordinate difference along the Z-axis between the mark three M3 and the mark four M4, the rotational angle difference (θ_{y}) may be calculated; through the planar distance difference along the Y-axis and the height coordinate difference along the Z-axis between the mark one M1 and the mark three M3, as well as the height coordinate difference along the Y-axis and Z-axis between the mark one M1 and the mark four M4, the rotational angle difference (θₓ) may be calculated; through the spatial coordinates of the center of the first fiber f1 and the center of the last fiber fn of the fiber optics 23, the rotational angle difference (θ_{z}) may be obtained, or through the difference between the center coordinates C1 and the center coordinates C2, the rotational angle difference (θ_{y}) may be calculated.

Please refer to FIG. 5E, which is similar to FIG. 5C and FIG. 5D, and the drawing contains the mark one M1, the mark two M2, and the mark four M4. Therefore after detecting the mark one M1, the mark two M2, the mark four M4, and each light emitting/receiving surface 23a of the fiber optic 23 with the upward-facing camera 120 to obtain the respective spatial coordinates thereof, the center coordinates C1 (obtained from the mark one M1, the mark two M2, and the mark four M4) and the center coordinates C2 (obtained from the light emitting/receiving surface 23a of the fiber optic 23) may be further obtained. Subsequently, through the planar distance difference along the X-axis and the height coordinate difference along the Z-axis between the mark one M1 and the mark two M2, and through the planar distance difference along the X-axis and the height coordinate difference along the Z-axis between the mark two M2 and the mark four M4, the rotational angle difference (θ_{y}) may be calculated; through the planar distance difference along the Y-axis and the height coordinate difference along the Z-axis between the mark one M1 and the mark four M4, as well as the height coordinate difference along the Y-axis and Z-axis between the mark two M2 and the mark four M4, the rotational angle difference (θₓ) may be calculated; through the spatial coordinates of the center of the first fiber f1 and the center of the last fiber fn of the fiber optics 23, the rotational angle difference (θ_{z}) may be obtained. Alternatively, through the difference between center coordinates C1 and the center coordinates C2, the rotational angle difference (θ_{z}) may be calculated.

Please refer to FIG. 5F, which is similar to FIG. 5C to FIG. 5D, and the drawing contains the mark one M1, the mark two M2, and the mark three M3. Therefore, after detecting the mark one M1, the mark two M2, the mark three M3, and each light emitting/receiving surface 23a of the fiber optic 23 with the upward-facing camera 120 to obtain the relative position coordinates thereof, the center coordinates C1 (obtained from the mark one M1, the mark two M2, and the mark three M3) and the center coordinates C2 (obtained from the light emitting/receiving surface 23a of the fiber optic 23) may be further obtained. Subsequently, through the planar distance difference along the X-axis and the height coordinate difference along the Z-axis between the mark one M1 and the mark two M2, and through the planar distance difference along the X-axis and the height coordinate difference along the Z-axis between the mark one M1 and the mark three M3, the rotational angle difference (θ_{y}) may be calculated; through the planar distance difference along the Y-axis and the height coordinate difference along the Z-axis between the mark one M1 and the mark three M3, as well as the height coordinate difference along the Y-axis and Z-axis between the mark two M2 and the mark three M3, the rotational angle difference (θₓ) may be calculated; through the spatial coordinates of the center of the first fiber f1 and the center of the last fiber fn of the fiber optics 23, the rotational angle difference (θ_{z}) may be obtained. Alternatively, through the difference between the center coordinates C1 and the center coordinates C2, the rotational angle difference (θ_{z}) may be calculated.

Please refer to FIG. 5G, in addition to the mark two M2 and the mark three M3 disposed on the first endface 21a, the configuration further includes a mark five M5 disposed on the second endface 22a, and the mark five M5 is located at a center position of the second endface 22a. After detecting the mark two M2, the mark three M3, the mark five M5, and each light emitting/receiving surface 23a of the fiber optic 23 with the upward-facing camera 120 to obtain the respective spatial coordinates thereof, the center coordinates C1 (obtained from the mark two M2, the mark three M3, and the mark five M5) and the center coordinates C2 (obtained from the light emitting/receiving surface 23a of the fiber optic 23) may be further obtained. Subsequently, through the planar distance difference along the X-axis and the height coordinate difference along the Z-axis between the mark two M2 and the mark five M5, and through the planar distance difference along the X-axis and the height coordinate difference along the Z-axis between the mark three M3 and the mark five M5, the rotational angle difference (θ_{y}) may be calculated; through the planar distance difference along the Y-axis and the height coordinate difference along the Z-axis between the mark two M2 and the mark three M3, the rotational angle difference (θₓ) may be calculated; through the spatial coordinates of the center of the first fiber f1 and the center of the last fiber fn of the fiber optics 23, the rotational angle difference (θ_{z}) may be obtained. Alternatively, through the difference between the center coordinates C1 and the center coordinates C2, the rotational angle difference (θ_{z}) may be calculated.

Please refer to FIG. 5H, which is similar to FIG. 5G, in addition to the mark one M1 and the mark four M4 disposed on the second endface 22a, the configuration further includes a mark six M6 disposed on the first endface 21a, and the mark six M6 is located at a center position of the first endface 21a. After detecting the mark one M1, the mark four M4, the mark six M6, and each light emitting/receiving surface 23a of the fiber optic 23 with the upward-facing camera 120 to obtain the respective spatial coordinates thereof, the center coordinates C1 (obtained from the mark one M1, the mark four M4, and the mark six M6) and the center coordinates C2 (obtained from the light emitting/receiving surface 23a of the fiber optic 23) may be further obtained. Subsequently, through the planar distance difference along the X-axis and the height coordinate difference along the Z-axis between the mark one M1 and the mark six M6, and through the planar distance difference along the X-axis and the height coordinate difference along the Z-axis between the mark four M4 and the mark six M6, the rotational angle difference (θ_{y}) may be calculated; through the planar distance difference along the Y-axis and the height coordinate difference along the Z-axis between the mark one M1 and the mark four M4, the rotational angle difference (θₓ) may be calculated; through the spatial coordinates of the center of the first fiber f1 and the center of the last fiber fn of the fiber optics 23, the rotational angle difference (θ_{z}) may be obtained. Alternatively, through the difference between the center coordinates C1 and the center coordinates C2, the rotational angle difference (θ_{z}) may be calculated.

In summary, in the foregoing embodiments of the disclosure, the optical fiber array includes physical marks disposed on the endface thereof for optical alignment, which serve as references for the upward-facing camera of the wafer prober during alignment. Therefore, with the plane of the coupler on the silicon photonics wafer as a reference, the upward-facing camera may successfully locate the relative position coordinates and angle of the optical fiber array with respect to the coupler. Furthermore, by incorporating the relative distances between multiple fiber optics of the optical fiber array and the marks, the correction amount required to drive the optical fiber array to the correct optical coupling position may be obtained through calculation. The correction amount includes relative coordinate differences and relative angle differences.

In the silicon photonics wafer testing system, compared to the poor coupling efficiency in existing optical fiber arrays caused by errors from clamping mechanisms or polishing processes, this disclosure effectively reduces the time and complexity required for optical coupling alignment and subsequent optical testing and opto-electronic testing through the rapid alignment actively provided for the optical fiber array as described above.

What is claimed is:

1. An optical fiber array capable of alignment adapted for a silicon photonics wafer testing system, wherein the silicon photonics wafer testing system comprises a wafer prober and an optical coupling actuator, the optical fiber array is loaded on the optical coupling actuator, the optical coupling actuator is disposed on the wafer prober, a silicon photonics wafer is loaded on the wafer prober, the optical fiber array is aligned through the wafer prober, so that the aligned optical fiber array reaches a state of being able to optically couple with a coupler of the silicon photonics wafer, and the optical fiber array comprises:
a plurality of fiber optics;
a base having a first endface and a plurality of grooves parallel to each other, wherein the fiber optics are disposed in the grooves, and one lateral opening of each of the grooves is located on the first endface;
a lid stacked on the base, and covering the grooves and portions of the fiber optics in the grooves to expose the lateral openings, wherein the lid has a second endface, the first endface of the base, light emitting/receiving surfaces of the fiber optics, and the second endface of the lid are located on same plane; and
a plurality of marks respectively disposed on the first endface and the second endface, wherein on the plane, the marks are located outside a range where the fiber optics are located.

2. The optical fiber array capable of alignment as claimed in claim 1, wherein the fiber optics are arranged along a first axis, and a first relative distance along the first axis between two of the marks is greater than an array length of the fiber optics along the first axis.

3. The optical fiber array capable of alignment as claimed in claim 2, wherein a second relative distance along a second axis between two of the marks is greater than an array length of the fiber optics along the second axis, and the second axis is orthogonal to the first axis.

4. The optical fiber array capable of alignment as claimed in claim 1, wherein a quantity of the marks is two, three, or four, and the marks are located at different corners with respect to the fiber optics.

5. The optical fiber array capable of alignment as claimed in claim 4, wherein two of the marks are diagonally disposed.

6. The optical fiber array capable of alignment as claimed in claim 4, further comprising at least another one of the marks disposed at a center position of one of the first endface and the second endface, and two of the marks disposed on the other one of the first endface and the second endface.

7. An alignment method of an optical fiber array for aligning the optical fiber array in the silicon photonics wafer testing system as claimed in claim 1, wherein the alignment method of the optical fiber array comprises:
driving an upward-facing camera of the wafer prober to detect the optical fiber array, and obtaining spatial coordinates of the light emitting/receiving surface of each of the fiber optics in the wafer prober and spatial coordinates of the marks in the wafer prober, so as to calculate a relative position difference and a relative angle difference of the optical fiber array with respect to the silicon photonics wafer.

8. The alignment method of the optical fiber array as claimed in claim 7, wherein the optical fiber array is located in rectangular coordinates (X-Y-Z) of the wafer prober, the silicon photonics wafer is situated on an X-Y plane, the relative angle difference comprises a rotational angle difference (θₓ) relative to an X-axis, a rotational angle difference (θ_{y}) relative to the Y-axis, and a rotational angle difference (θ_{z}) relative to the Z-axis.

9. The alignment method of the optical fiber array as claimed in claim 8, further comprising: calculating the rotational angle difference (θₓ θ_{y}) through positions of centers of the marks in the rectangular coordinates (X-Y-Z).

10. The alignment method of the optical fiber array as claimed in claim 8, further comprising: calculating the rotational angle difference (θ_{z}) through positions of the marks relative to a first fiber of the fiber optics in the rectangular coordinates (X-Y-Z) and through positions of the marks relative to a last fiber of the fiber optics in the rectangular coordinates (X-Y-Z).

11. The alignment method of the optical fiber array as claimed in claim 7, wherein a quantity of the marks is two, three, or four, and the marks are located at different corners with respect to the fiber optics.

12. The alignment method of the optical fiber array as claimed in claim 11, wherein two of the marks are diagonally disposed.

13. The alignment method of the optical fiber array as claimed in claim 11, further comprising at least another one of the marks disposed at a center position of one of the first endface and the second endface, and two of the marks disposed on the other one of the first endface and the second endface.

14. The alignment method of the optical fiber array as claimed in claim 7, wherein the wafer prober comprises a movable stage disposed in a probe testing platform of the wafer prober, the optical coupling actuator is disposed on the probe testing platform, the upward-facing camera is disposed on a side of the movable stage, and the silicon photonics wafer is loaded on the movable stage.
